(19) United States
(12) Patent Application Publication
(10) Pub. No.: US 2025/0151435 A1
(43) Pub. Date: May 8, 2025

(54) SOLID-STATE IMAGE SENSOR

(71) Applicant: VisEra Technologies Company Limited, Hsin-Chu City (TW)

(72) Inventors: Ching-Hua LI, Hsin-Chu City (TW); Chun-Yuan WANG, Hsin-Chu City (TW); Po-Hsiang WANG, Hsin-Chu City (TW); Han-Lin WU, Hsin-Chu City (TW); Hung-Jen TSAI, Hsin-Chu City (TW)

(21) Appl. No.: 18/501,460

(22) Filed: Nov. 3, 2023

(51) Int. Cl. H01L 27/146

(52) U.S. Cl. CPC H10F 39/8057; H10F 39/8053

(57) ABSTRACT

A solid-state image sensor is provided. The solid-state image sensor includes photoelectric conversion elements and a color filter layer disposed above the photoelectric conversion elements. The color filter layer has a first color filter segment and a second color filter segment adjacent to the first color filter segment. The first color filter segment and the second color filter segment correspond to different colors. The solid-state image sensor also includes a shielding grid structure disposed between the first color filter segment and the second color filter segment. The shielding grid structure is divided into a first shielding segment and a second shielding segment. The solid-state image sensor further includes a meta structure disposed above the color filter layer. In a top view, the second shielding segment is formed as a triangle, a rectangle, or a combination thereof.

### BACKGROUND OF THE INVENTION

### Field of the Invention

The embodiments of the present disclosure relate to image sensors, and in particular they relate to solid-state image sensors that include a shielding grid structure for phase detection auto focus (PDAF).

### Description of the Related Art

Solid-state image sensors (e.g., complementary metal-oxide semiconductor (CMOS) image sensors) are widely used in various image-capturing apparatuses such as digital still-image cameras, digital video cameras, and the like. Signal electric charges may be generated according to the amount of light received in the light-sensing portion (e.g., the photoelectric conversion element) of the solid-state image sensor. In addition, the signal electric charges generated in the light-sensing portion may be transmitted and amplified, whereby an image signal is obtained.

Recently, the trend has been for the pixel size of image sensors typified by CMOS image sensors to be reduced for the purpose of increasing the number of pixels to provide high-resolution images. Although existing solid-state image sensors have been generally adequate for their intended purposes, they have not been entirely satisfactory in all respects. For example, meta structures are wildly used in the image sensors. However, when an oblique incident light (e.g., the chief ray angle (CRA) is not equal to 0) directly radiates into the image sensor, the incident light may be directly collected by the photoelectric conversion elements (e.g., photodiodes (PD)), so that the meta structures do not have a significant phase-detection auto-focus (PDAF) ratio.

### BRIEF SUMMARY OF THE INVENTION

According to the embodiments of the present disclosure, the solid-state image sensor includes a shielding grid structure below the meta structure, and the shielding grid structure has a specific shape that may help the meta structure to have a PDAF function.

An embodiment of the present invention provides a solid-state image sensor. The solid-state image sensor includes photoelectric conversion elements and a color filter layer disposed above the photoelectric conversion elements. The color filter layer has a first color filter segment and a second color filter segment adjacent to the first color filter segment. The first color filter segment and the second color filter segment correspond to different colors. The solid-state image sensor also includes a shielding grid structure disposed between the first color filter segment and the second color filter segment. The shielding grid structure is divided into a first shielding segment and a second shielding segment. The solid-state image sensor further includes a meta structure disposed above the color filter layer. In a top view, the second shielding segment is formed as a triangle, a rectangle, or a combination thereof.

In some embodiments, in a cross-sectional view, the first width of the first shielding segment is different from the second width of the second shielding segment.

In some embodiments, in the top view, the first color filter segment or the second color filter segment is divided into four sub-segments along the X-axis and the Y-axis that is perpendicular to the X-axis.

In some embodiments, the second shielding segment is symmetrical with respect to the symmetry axis, and an included angle between the symmetry axis and the X-axis or between the symmetry axis and the Y-axis is 45°.

In some embodiments, the second shielding segment is formed as a right triangle, and an included angle between a hypotenuse of the right triangle and the X-axis is between 20° and 80°.

In some embodiments, the relationship between the hypotenuse of the right triangle and the X-axis and Y-axis conforms to the following formula: Y=±mX+b, wherein m=0.36˜5.67, and b=±(0.05˜0.5)×the width of the first color filter segment.

In some embodiments, solid-state image sensor further includes an isolation structure disposed between the photoelectric conversion elements.

In some embodiments, the isolation structure has first isolation segments that correspond to the shielding grid structure and second isolation segments that divide the first color filter segment and the second color filter segment into sub-segments.

In some embodiments, each sub-segment defines a pixel, and a height of the shielding grid structure is in a range from 20 nm to 0.5×the width of the pixel.

In some embodiments, from a cross-sectional view, the first width of the first shielding segment is below 0.25×the width of the pixel, and the second width of the second shielding segment is (0.5˜1.5)×the width of the pixel.

In some embodiments, in the top view, the second shielding segment has a horizontal width along the first direction and a vertical width along the second direction. The second direction is perpendicular to the first direction. The difference between the horizontal width and the vertical width is (0˜1)×the width of the pixel.

In some embodiments, some sub-segments partially correspond to the second shielding segment and other sub-segments fully correspond to the second shielding segment.

In some embodiments, the solid-state image sensor further includes a dielectric grid structure disposed on the shielding grid structure.

In some embodiments, the dielectric grid structure fully covers the shielding grid structure.

In some embodiments, the dielectric grid structure is divided into a first grid segment that is disposed on the first shielding segment and a second grid segment that is disposed on the second shielding segment.

In some embodiments, in a cross-sectional view, the first grid segment and the second grid segment have the same width, and a portion of the second shielding segment extends beyond the second grid segment.

In some embodiments, the width of the first grid segment is equal to the first width of the first shielding segment, and the width of the second grid segment is equal to the second width of the second shielding segment.

In some embodiments, the first color filter segment is a blue color filter segment or a red color filter segment and the second color filter segment is a green color filter segment.

In some embodiments, there are multiple first color filter segments, second color filter segments, first shielding segments, and second shielding segments, and a pair of second shielding segments correspond to the second color filter segments, or a pair of second shielding segments correspond to the first color filter segment.

In some embodiments, in a cross-sectional view, widths of the second shielding segments become narrower from the central region of the solid-state image sensor to the edge of the solid-state image sensor.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1A is a cross-sectional view illustrating a portion of the solid-state image sensor in accordance with some embodiments of the present disclosure.

FIG. 1B and FIG. 1C are partial top views illustrating different components of the solid-state image sensor in accordance with some embodiments of the present disclosure.

FIG. 2A, FIG. 2B, and FIG. 2C are top views illustrating the second shielding segment according to different embodiments of the present disclosure.

FIG. 3A, FIG. 3B, and FIG. 3C are top views illustrating the second shielding segment according to different embodiments of the present disclosure.

FIG. 4 is a partial perspective view illustrating the shielding grid structure according to some embodiments of the present disclosure.

FIG. 5A and FIG. 5B are partial top views illustrating another arrangement of the second shielding segments in accordance with some other embodiments of the present disclosure.

FIG. 6A and FIG. 6B are cross-sectional views illustrating two regions of the solid-state image sensor in accordance with some embodiments of the present disclosure.

FIG. 7 is a cross-sectional view illustrating a portion of the solid-state image sensor in accordance with some embodiments of the present disclosure.

FIG. 8 is a cross-sectional view illustrating a portion of the solid-state image sensor in accordance with some embodiments of the present disclosure.

FIG. 9A to FIG. 16A and FIG. 9B to FIG. 16B are partial top views illustrating another arrangement of the second shielding segments in accordance with some other embodiments of the present disclosure.

FIG. 17 is a cross-sectional view illustrating a portion of the solid-state image sensor in accordance with some embodiments of the present disclosure.

FIG. 18A is a cross-sectional view illustrating a portion of the solid-state image sensor in accordance with some embodiments of the present disclosure.

FIG. 18B is a partial top view illustrating an arrangement of the second shielding segments in accordance with some embodiments of the present disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

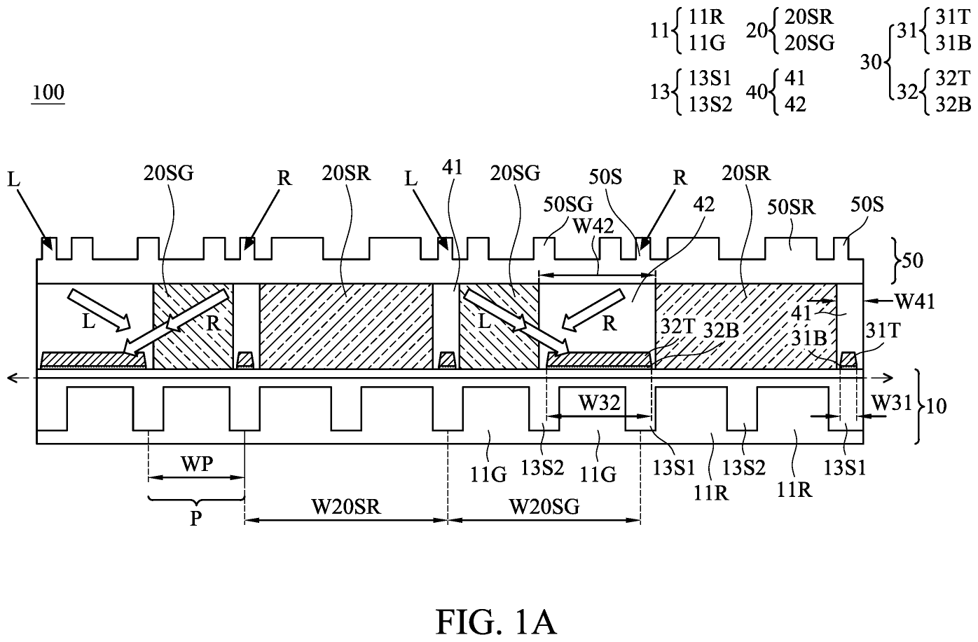

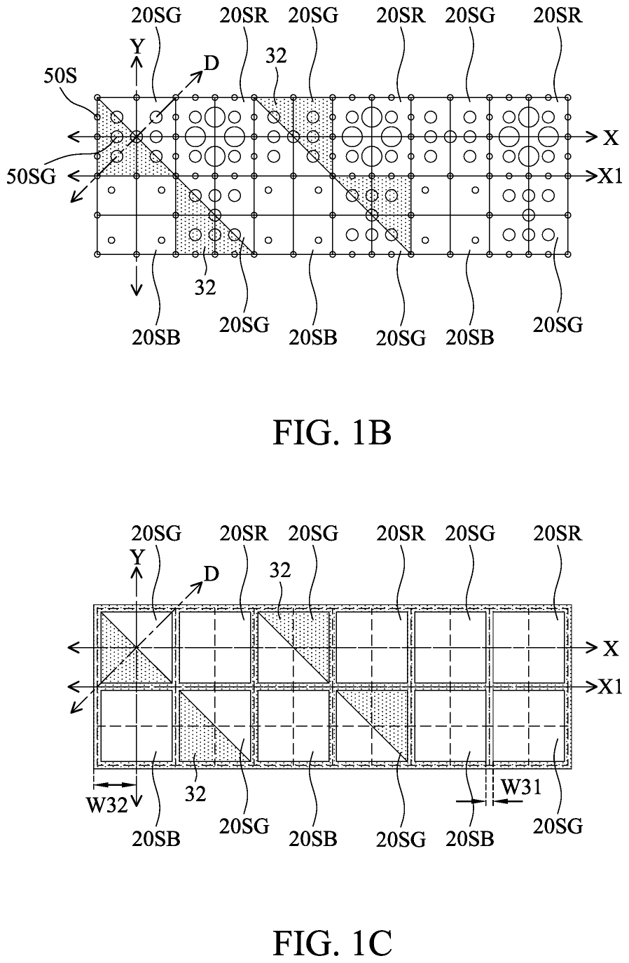

FIG. 1A is a cross-sectional view illustrating a portion of the solid-state image sensor 100 in accordance with some embodiments of the present disclosure. FIG. 1B and FIG. 1C are partial top views illustrating different components of the solid-state image sensor 100 in accordance with some embodiments of the present disclosure. For example, FIG. 1A may be a partial cross-sectional view of the solid-state image sensor 100 along line X-axial in FIG. 1B and FIG. 1C, but the present disclosure is not limited thereto. It should be noted that some components of the solid-state image sensor 100 have been omitted in FIG. 1A to FIG. 1C for the sake of brevity.

Referring to FIG. 1A, in some embodiments, the solid-state image sensor 100 includes a semiconductor substrate 10. The semiconductor substrate 10 may be a wafer or a chip. For example, the semiconductor substrate 10 may include silicon, but the present disclosure is not limited thereto.

As shown in FIG. 1A, in some embodiments, the semiconductor substrate 10 has a plurality of photoelectric conversion elements 11 (e.g., photoelectric conversion elements 11G and photoelectric conversion elements 11R). The photoelectric conversion elements 11 may be used for receiving different color lights. For example, the photoelectric conversion elements 11G may be used for receiving green light, and the photoelectric conversion elements 11R may be used for receiving red light, but the present disclosure is not limited thereto. The semiconductor substrate 10 may have other photoelectric conversion elements that are used for receiving, for example, green, yellow, white, cyan light, or IR/NIR, which may be adjusted depending on actual needs.

Referring to FIG. 1A, in some embodiments, the solid-state image sensor 100 includes an isolation structure 13 disposed between the photoelectric conversion elements 11. For example, the isolation structure 13 may include a shallow trench isolation (STI) or a deep trench isolation (DTI). The isolation structure 13 may be formed in the semiconductor substrate 10 using etching process to form trenches and filling the trenches with an insulating or dielectric material, but the present disclosure is not limited thereto.

As shown in FIG. 1A, in some embodiments, the isolation structure 13 has (or is divided into) first isolation segments 13S1 and second isolation segments 13S2. The first isolation segments 13S1 are disposed between the photoelectric conversion elements 11G and the photoelectric conversion elements 11R, and the second isolation segments 13S2 are disposed between the photoelectric conversion elements 11G and between the photoelectric conversion elements 11R. In other words, the first isolation segments 13S1 may be used to separate the photoelectric conversion elements 11 that receive different color lights, and the second isolation segments 13S2 may be used to separate the photoelectric conversion elements 11 that receive the same color light. It should be noted that the first isolation segments 13S1 and the second isolation segments 13S2 are illustrated as dashed lines in the top view of FIG. 1C.

Referring to FIG. 1A to FIG. 1C, in some embodiments, the solid-state image sensor 100 includes a color filter layer 20 disposed above the photoelectric conversion elements 11 (the semiconductor substrate 10). In some embodiments, the color filter layer 20 has (or is divided into) color filter segments that correspond to the photoelectric conversion elements 11. For example, as shown in FIG. 1A, the color filter layer 20 may have a green color filter segment 20SG that corresponds to the photoelectric conversion elements 11G, and a red color filter segment 20SR that corresponds to the photoelectric conversion elements 11R. Moreover, the green color filter segment 20SG is adjacent to the red color filter segment 20SR.

As shown in FIG. 1B and FIG. 1C, the color filter layer 20 may also have a blue color filter segment 20SB that corresponds to another photoelectric conversion element (not shown in FIG. 1A), but the present disclosure is not limited thereto. In some other embodiments, the color filter layer 20 has (or is divided into) other color filter segments. For example, the color filter layer 20 may have a yellow color filter segment, a white color filter segment, a cyan color filter segment, a magenta color filter segment, or an IR/NIR color filter, but the present disclosure is not limited thereto.

Referring to FIG. 1A to FIG. 1C, in some embodiments, the solid-state image sensor 100 includes a shielding grid structure 30 disposed between the green color filter segment 20SG and the red color filter segment 20R. The shielding grid structure 30 may include metal. For example, the metal may include gold (Au), nickel (Ni), platinum (Pt), palladium (Pd), iridium (Ir), titanium (Ti), chromium (Cr), tungsten (W), aluminum (Al), copper (Cu), the like, an alloy thereof, or a combination thereof, but the present disclosure is not limited thereto.

As shown in FIG. 1A to FIG. 1C, in some embodiments, the shielding grid structure 30 is divided into first shielding segments 31 and second shielding segments 32. In this embodiment, the first shielding segment 31 includes a bottom portion 31B and a top portion 31T disposed on the bottom portion 31B, and the second shielding segment 32 includes a bottom portion 32B and a top portion 32T disposed on the bottom portion 32B. For example, the bottom portion 31B of the first shielding segment 31 and the bottom portion 32B of the second shielding segment 32 may include titanium nitride (TiN), and the top portion 31T of the first shielding segment 31 and the top portion 32T of the second shielding segment 32 may include tungsten (W), but the present disclosure is not limited thereto.

As shown in FIG. 1A to FIG. 1C, in some embodiments, the first isolation segments 13S1 correspond to the shielding grid structure 30, and the second isolation segments 13S2 divide the green color filter segment 20SG, the red color filter segment 20SR, and the blue color filter segment 20SB into sub-segments. For example, as shown in FIG. 1B and FIG. 1C, each color filter segment is divided into four sub-segments. As shown in FIG. 1A (and FIG. 1B and FIG. 1C), in some embodiments, each sub-segment defines a pixel P.

As shown in FIG. 1B and FIG. 1C, in some embodiments, in the top view (e.g., FIG. 1B or FIG. 1C), each of the green color filter segment 20SG, the red color filter segment 20SR, and the blue color filter segment 20SB is divided into four sub-segments along the X-axis and the Y-axis that is perpendicular to the X-axis. In this embodiment, the second shielding segment 32 is formed as a triangle. Moreover, the second shielding segment 32 is symmetrical with respect to the symmetry axis D, and an included angle between the symmetry axis D and the X-axis or between the symmetry axis D and the Y-axis is about 45°. Moreover, in some embodiments, some sub-segments (of the green color filter segment 20SG) partially correspond to the second shielding segment 32, and other sub-segments (of the green color filter segment 20SG) fully correspond to the second shielding segment 32.

As shown in FIG. 1A, in some embodiments, in a cross-sectional view (e.g., FIG. 1A), the first width W31 of the first shielding segment 31 is different from the second width W32 of the second shielding segment 32. In more detail, the first width W31 of the first shielding segment 31 is less the second width W32 of the second shielding segment 32, but the present disclosure is not limited thereto. As shown in FIG. 1A to FIG. 1C, in this embodiment, the second shielding segments 32 correspond to the green color filter segments 20SG.

As shown in FIG. 1A, in some embodiments, in a cross-sectional view (e.g., FIG. 1A), the first width W31 of the first shielding segment 31 is below about 0.25×the width WP of the pixel, and the second width W32 of the second shielding segment 32 is about (0.5˜1.5)×the width WP of the pixel.

Referring to FIG. 1A, in some embodiments, the solid-state image sensor 100 includes a meta structure 50 disposed above the color filter layer 20 (and the shielding grid structure 30). The meta structure 50 includes pillars (e.g., 50S, 50SG, and 50SR). For example, the pillars 50SG may correspond to green color filter segment 20SG, the pillars 50SR may correspond to red color filter segment 20SR, and the pillars 50S may correspond to the shielding grid structure 30, but the present disclosure is not limited thereto. In this embodiment, the pillars 50S, 50SG, and 50SR have different sizes (e.g., different diameters). For example, the pillars 50S, 50SG, and 50SR may include glass, epoxy resin, silicone resin, polyurethane, any other applicable material, or a combination thereof, but the present disclosure is not limited thereto.

As shown in FIG. 1A, lights penetrates the meta structure 50 from the right side (i.e., light R) and lights penetrates the meta structure 50 from the left side (i.e., light L) may be absorbed in different absorption rates because of the shielding grid structure 30, so that the meta structure 50 may have a PDAF function.

Referring to FIG. 1A, in some embodiments, the solid-state image sensor 100 further includes a dielectric grid structure 40 disposed on the shielding grid structure 30. For example, the dielectric grid structure 40 may include a transparent dielectric material that has a low refractive index in a range from about 1.0 to about 1.99. In some embodiments, the refractive index of the dielectric grid structure 40 is lower than the refractive index of the color filter layer 20 (that includes red color filter segment 20SR, green color filter segment 20SG, blue color filter segment 20SB).

As shown in FIG. 1A, in this embodiment, the dielectric grid structure 40 fully covers the shielding grid structure 30. In some embodiments, in the cross-sectional view, the dielectric grid structure 40 has (or is divided into) a first grid segment 41 and a second grid segment 42. The first grid segment 41 is disposed on the first shielding segment 31, and the second grid segment 42 is disposed on the second shielding segment 32. In other words, in the cross-sectional view, the width W41 of the first grid segment 41 is less than the width W42 of the second grid segment 42, but the present disclosure is not limited thereto.

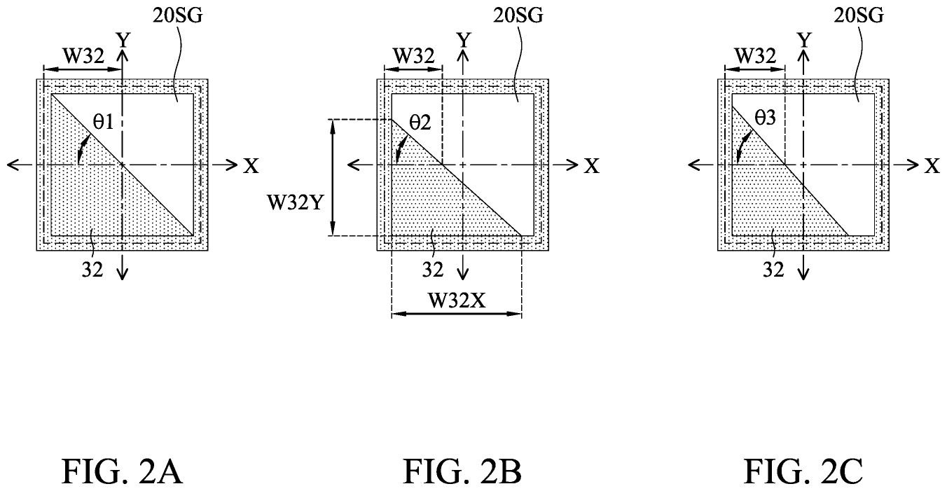

FIG. 2A, FIG. 2B, and FIG. 2C are top views illustrating the second shielding segment 32 according to different embodiments of the present disclosure. Referring to FIG. 2A to FIG. 2C, in these embodiments, in the top view, the second shielding segment 32 is formed as a right triangle. An included angle θ1, θ2, or θ3 between the hypotenuse of the right triangle and the X-axis is between about 200 and about 80°.

Moreover, in some embodiments, in the top view (e.g., FIG. 2B), the second shielding segment 32 has a horizontal width W32X along the X-direction and a vertical width W32Y along the Y-direction. The Y-direction is perpendicular to the X-direction. In some embodiments, the difference between the horizontal width W32X and the vertical width W32Y is about (0˜1)×the width of the pixel WP.

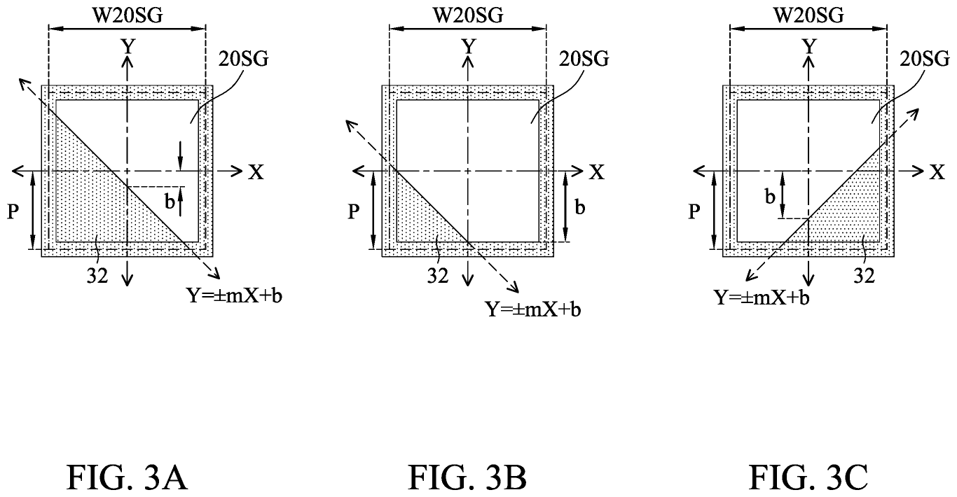

FIG. 3A, FIG. 3B, and FIG. 3C are top views illustrating the second shielding segment 32 according to different embodiments of the present disclosure. Referring to FIG. 3A to FIG. 3C, in these embodiments, in the top view, the second shielding segment 32 is formed as a right triangle. In some embodiments, the relationship between the hypotenuse of the right triangle and the X-axis and Y-axis conforms to the following formula: Y=±mX+b, where m=0.36˜5.67, and b=±(0.05˜0.5)×the width W20SG of the green color filter segment 20SG (or the red color filter segment 20SR or the blue color filter segment 20SB).

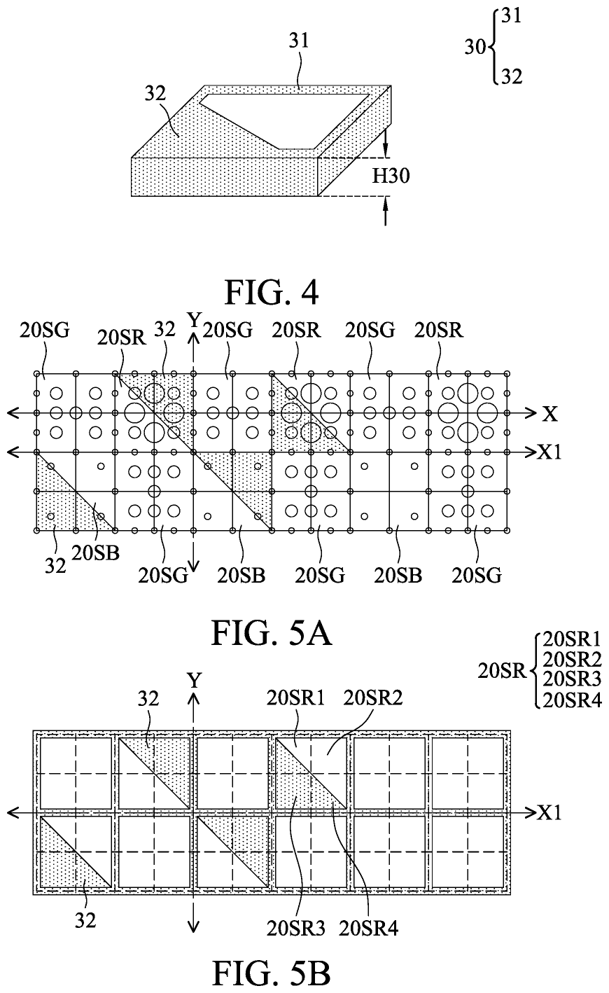

FIG. 4 is a partial perspective view illustrating the shielding grid structure 30 according to some embodiments of the present disclosure. It should be noted that only one second shielding segment 32 is shown in FIG. 4. Referring to FIG. 4, in some embodiments, the height H30 of the shielding grid structure 30 is in a range from about 20 nm to about 0.5×the width WP of the pixel P.

FIG. 5A and FIG. 5B are partial top views illustrating another arrangement of the second shielding segments 32 in accordance with some other embodiments of the present disclosure. As shown in FIG. 5A and FIG. 5B, there are two pair of second shielding segments 32 (i.e., four second shielding segments 32), and these two pair of second shielding segments 32 correspond to the blue color filter segment 20SB and the red color filter segment 20SR.

Similarly, in this embodiment, in the top view, the second shielding segment 32 is formed as a right triangle, some sub-segments partially correspond to the second shielding segment 32, and other sub-segments fully correspond to the second shielding segment 32. For example, the sub-segments 20SR1 and 20SR4 partially correspond to the second shielding segment 32, and the sub-segment 20SR3 fully correspond to the second shielding segment 32, but the present disclosure is not limited thereto.

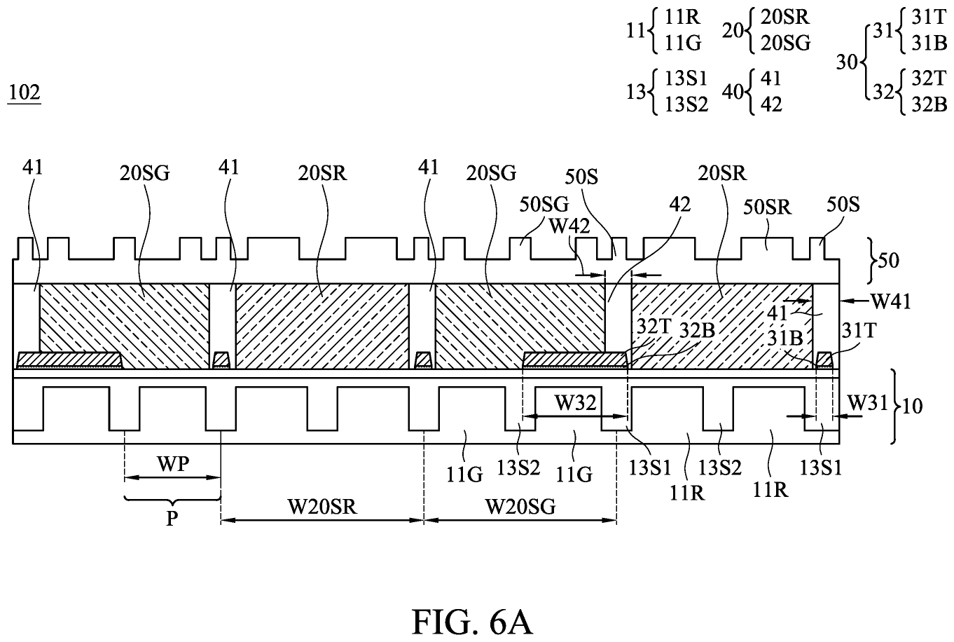

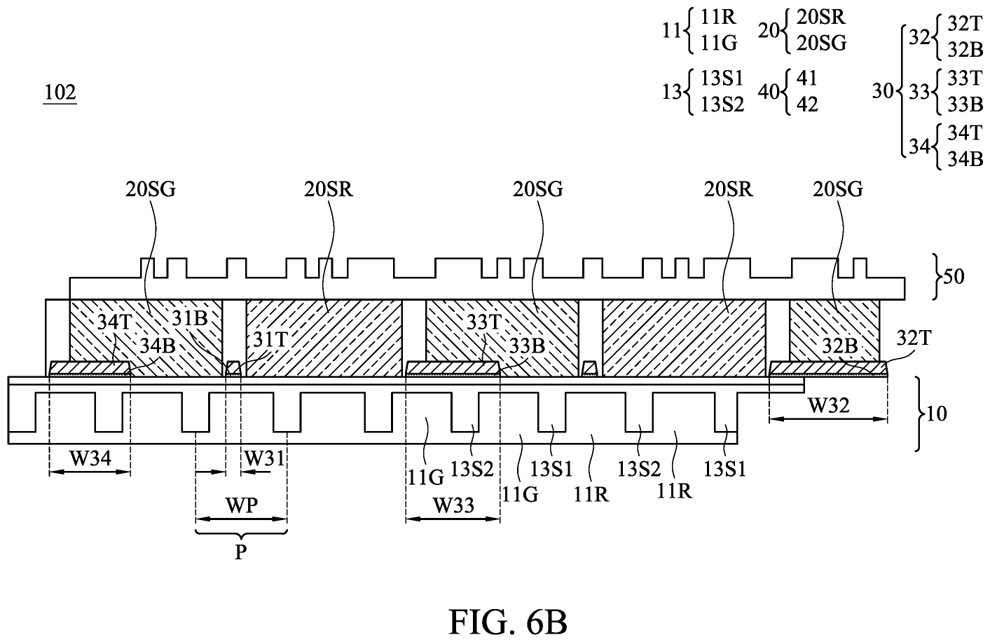

FIG. 6A and FIG. 6B are cross-sectional views illustrating two regions of the solid-state image sensor 102 in accordance with some embodiments of the present disclosure. For example, FIG. 1A may show the central region of the solid-state image sensor 102, and FIG. 1B may show the edge of the solid-state image sensor 102. Similarly, some components of the solid-state image sensor 102 have been omitted in FIG. 6A and FIG. 6B for the sake of brevity.

In the cross-sectional view shown in FIG. 6A (i.e., in the central region of the solid-state image sensor 102), the first grid segment 41 and the second grid segment 42 of the dielectric grid structure 40 have the same width. Moreover, a portion of the second shielding segment 32 extends beyond the second grid segment 42 of the dielectric grid structure 40.

In some embodiments, the width of each second shielding segment becomes narrower from the central region to the edge of the solid-state image sensor 102. For example, in the cross-sectional view shown in FIG. 6B (i.e., in the edge of the solid-state image sensor 102), the second width W32 of the second shielding segment 32 is greater than the second width W33 of the second shielding segment 33, and the second width W33 of the second shielding segment 33 is greater than the second width W34 of the second shielding segment 34.

Similarly, as shown in FIG. 6B, the second shielding segment 33 includes a bottom portion 33B and a top portion 33T disposed on the bottom portion 33B, and the second shielding segment 34 includes a bottom portion 34B and a top portion 34T disposed on the bottom portion 34B, but the present disclosure is not limited thereto.

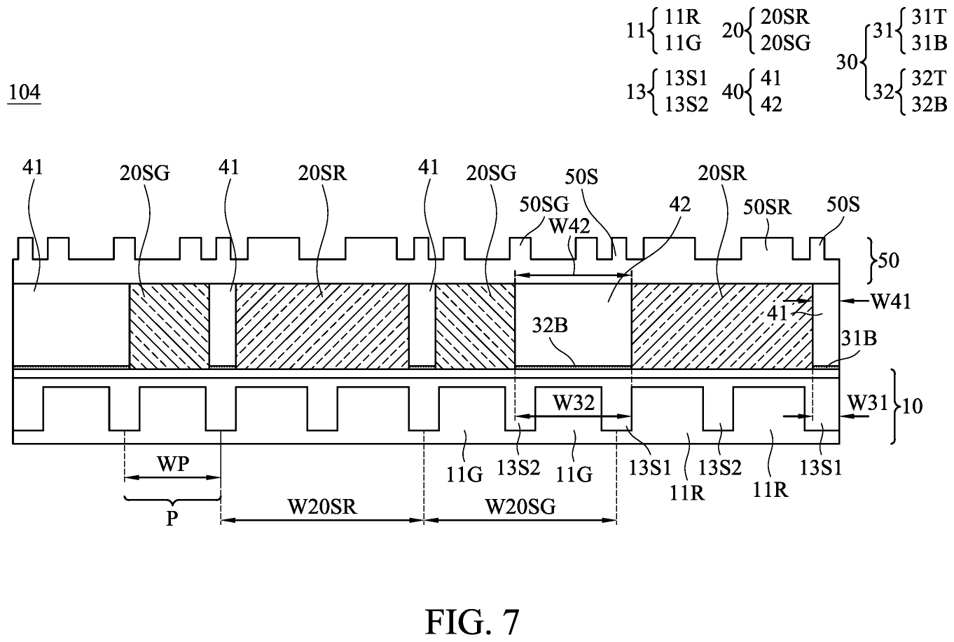

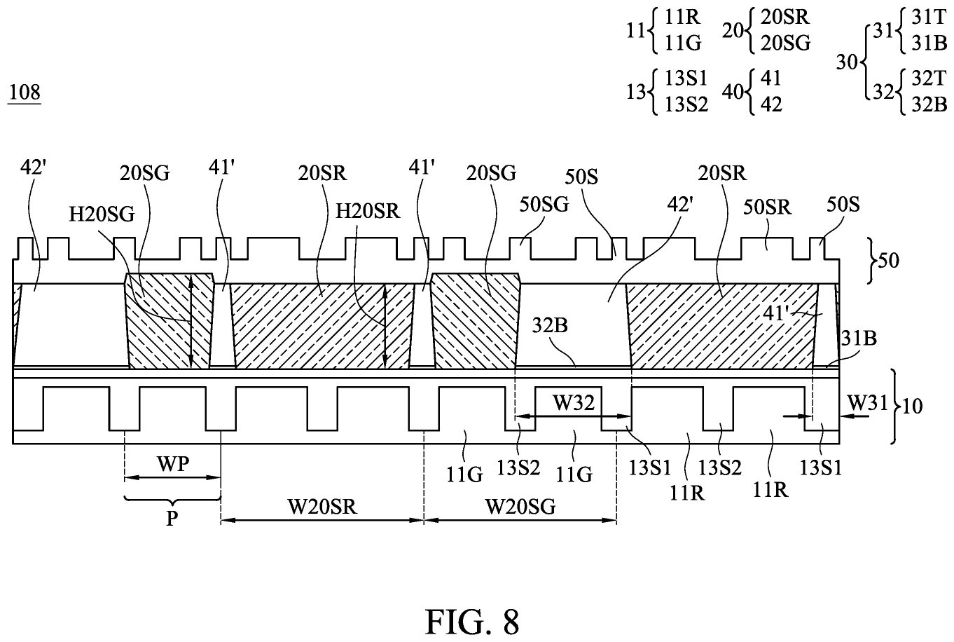

FIG. 7 is a cross-sectional view illustrating a portion of the solid-state image sensor 104 in accordance with some embodiments of the present disclosure. FIG. 8 is a cross-sectional view illustrating a portion of the solid-state image sensor 106 in accordance with some embodiments of the present disclosure. Similarly, some components of the solid-state image sensors 104 and 106 have been omitted in FIG. 7 and FIG. 8 for the sake of brevity.

Referring to FIG. 7, the solid-state image sensor 106 may have a similar structure to the solid-state image sensor 100 shown in FIG. 1A. The main difference from the image sensor 100 shown in FIG. 1A is that in the embodiment shown in FIG. 7, the first shielding segment 31 includes the bottom portion 31B without the top portion 31T, and the second shielding segment 32 includes the bottom portion 32B without the top portion 32T.

Moreover, in this embodiment, the width W41 of the first grid segment 41 is substantially equal to the first width W31 of the first shielding segment 31, and the width W42 of the second grid segment 42 is substantially equal to the second width W32 of the second shielding segment 32.

Referring to FIG. 8, the solid-state image sensor 108 may have a similar structure to the solid-state image sensor 106 shown in FIG. 7. The main difference from the image sensor 106 shown in FIG. 7 is that in the embodiment shown in FIG. 8, the height H20SG of the green color filter segment 20SG is higher than the height H20SR of the red color filter segment 20SR. Moreover, in the cross-sectional view, each of the first grid segment 41 and the second grid segment 42 is formed as a trapezoid with a narrower top and a wider bottom.

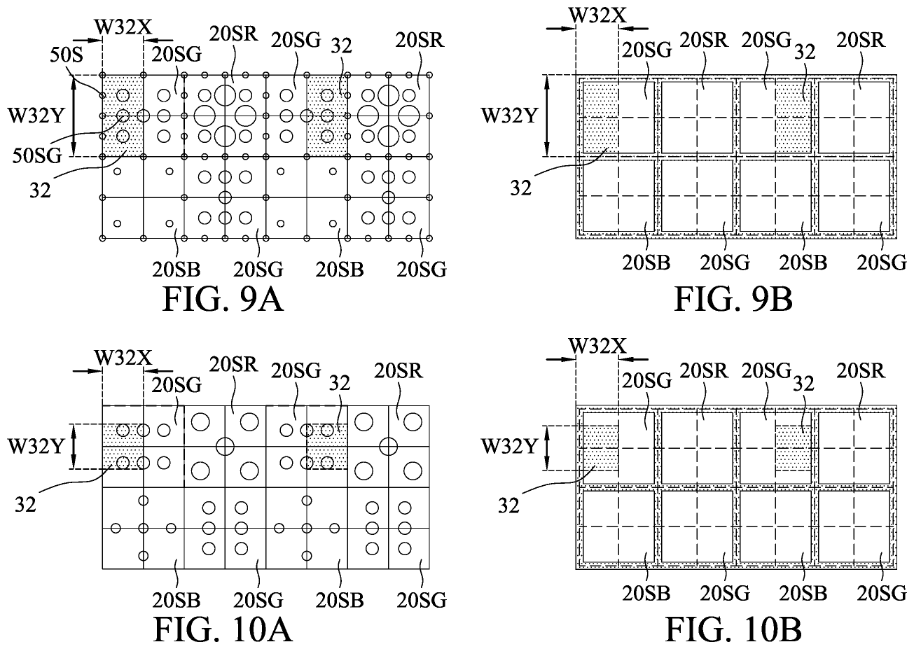

FIG. 9A to FIG. 16A and FIG. 9B to FIG. 16B are partial top views illustrating another arrangement of the second shielding segments 32 in accordance with some other embodiments of the present disclosure. As shown in FIG. 9A and FIG. 9B, in the top view of this embodiment, the second shielding segment 32 is formed as a rectangle. In this embodiment, each second shielding segments 32 correspond to two sub-segments of the green color filter segment 20SG. Moreover, in the top view of this embodiment, the second shielding segment 32 has a horizontal width W32X along the X-direction and a vertical width W32Y along the Y-direction that is perpendicular to the X-direction. The vertical width W32Y is greater than the horizontal width W32X.

As shown in FIG. 10A and FIG. 10B, in the top view of this embodiment, the second shielding segment 32 is formed as a square. Similarly, each second shielding segments 32 correspond to two sub-segments of the green color filter segment 20SG. Moreover, in the top view of this embodiment, the second shielding segment 32 has a horizontal width W32X along the X-direction and a vertical width W32Y along the Y-direction. The Y-direction is perpendicular to the X-direction. The vertical width W32Y is substantially equal to the horizontal width W32X.

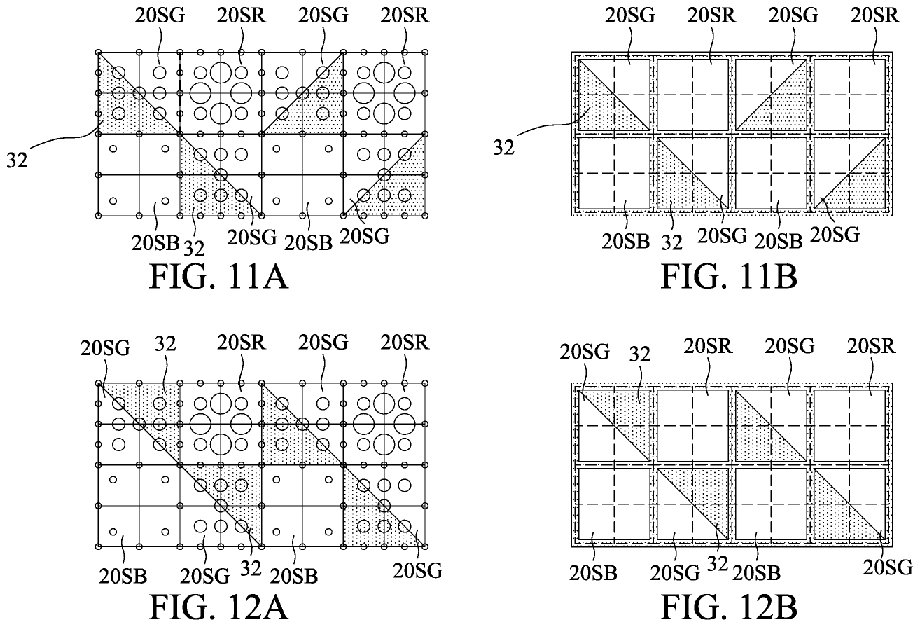

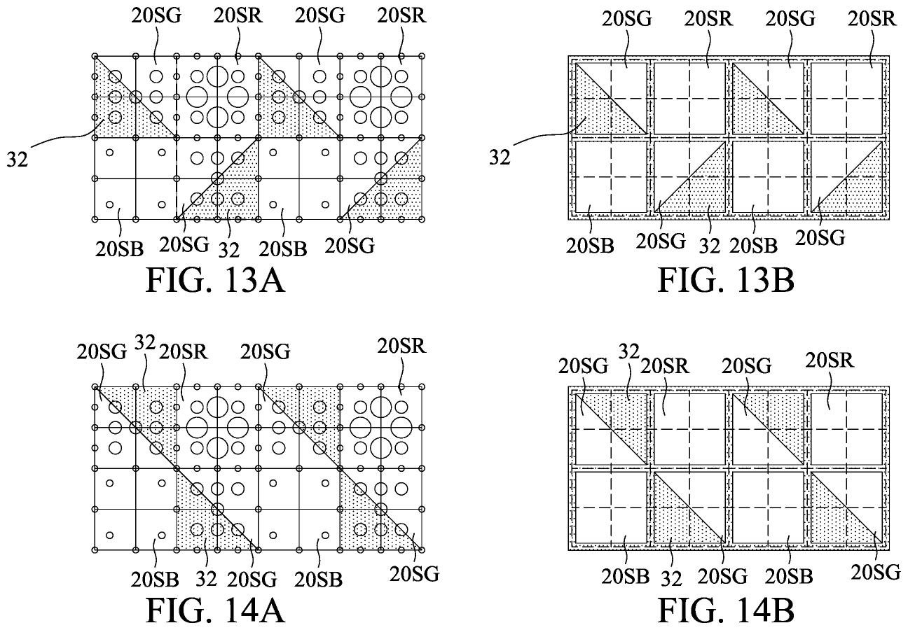

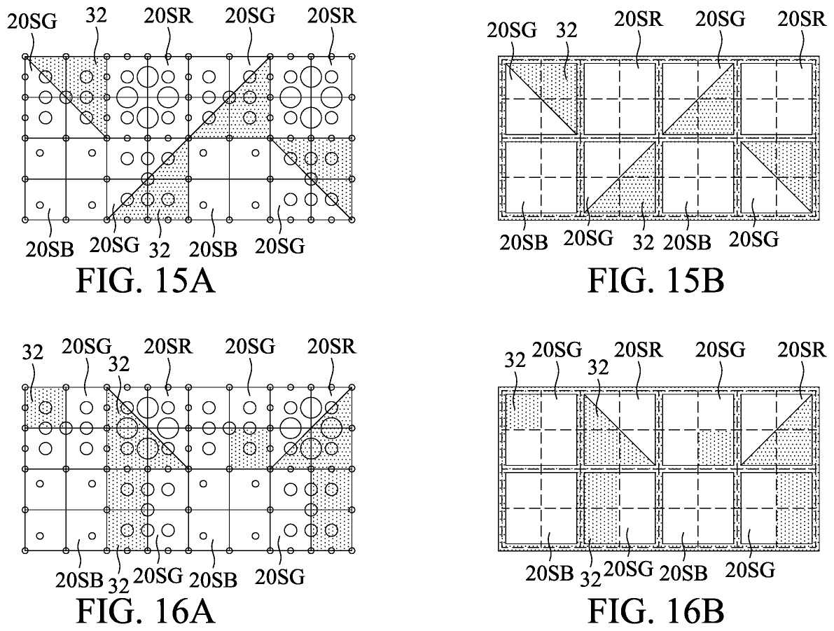

As shown in FIG. 11A and FIG. 11B, FIG. 12A and FIG. 12B, FIG. 13A and FIG. 13B, FIG. 14A and FIG. 14B, and FIG. 15A and FIG. 15B, in the top view of these embodiments, the second shielding segment 32 is formed as a right triangle. Moreover, each second shielding segments 32 correspond to three sub-segments of the green color filter segment 20SG (e.g., two sub-segments partially correspond to the second shielding segment 32 and one sub-segment fully corresponds to the second shielding segment 32).

As shown in FIG. 16A and FIG. 16B, in the top view of this embodiment, the second shielding segment 32 is formed as a square, a rectangle, and a triangle. In this embodiment, each square second shielding segment 32 and each rectangle second shielding segment 32 respectively correspond to one and two sub-segments of the green color filter segment 20SG. Moreover, each triangle second shielding segments 32 correspond to three sub-segments of the red color filter segment 20SR (e.g., two sub-segments partially correspond to the second shielding segment 32 and one sub-segment fully corresponds to the second shielding segment 32).

Although the second shielding segment 32 is formed as a rectangle (that includes a square), or a triangle in the foregoing embodiments, the present disclosure is not limited thereto. In some other embodiments, in a top view, the second shielding segment 32 is formed as a combination of a triangle and a rectangle, such as a trapezoid.

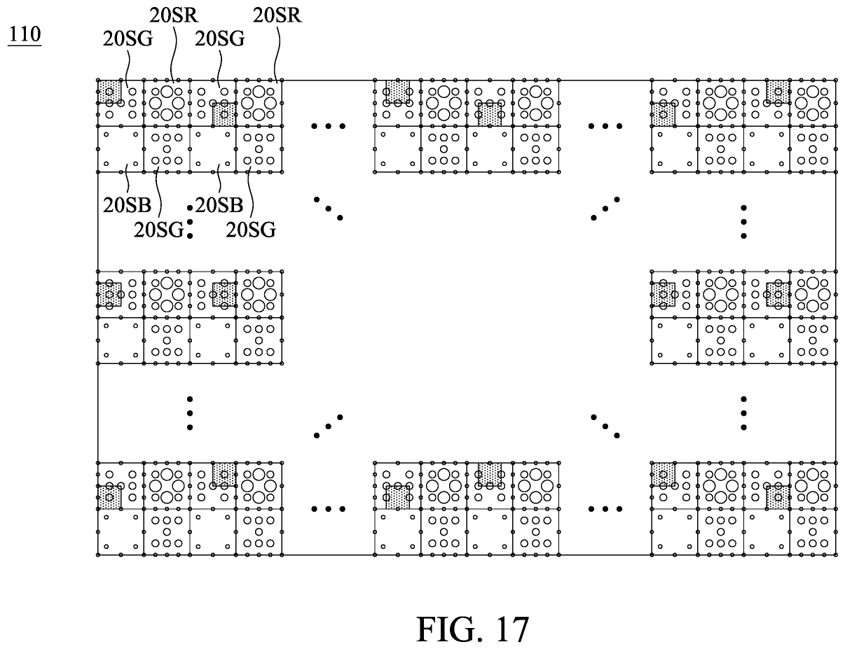

FIG. 17 is a cross-sectional view illustrating a portion of the solid-state image sensor 110 in accordance with some embodiments of the present disclosure. Similarly, some components of the solid-state image sensor 110 have been omitted in FIG. 17 for the sake of brevity.

FIG. 17 is a cross-sectional view showing the central region to the edge of the solid-state image sensor 110. Referring to FIG. 17, in this embodiments, the second shielding segments 32 are substantially arranged along the radial direction from the central region to the edge of the solid-state image sensor 110.

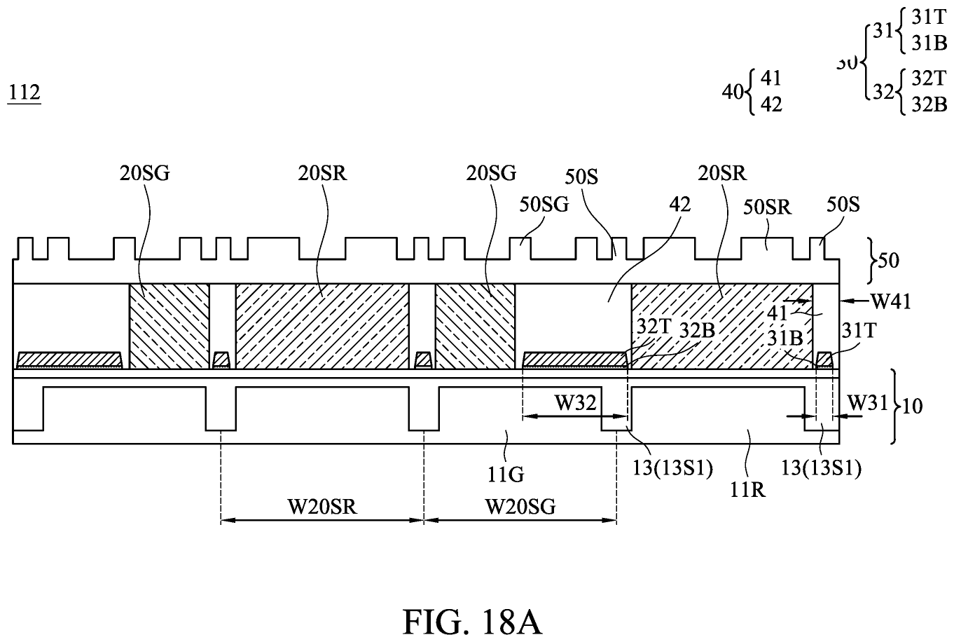

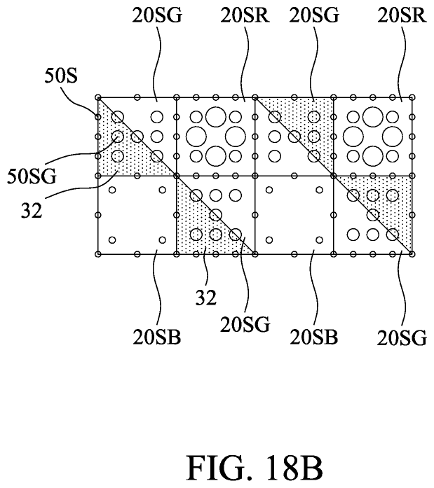

FIG. 18A is a cross-sectional view illustrating a portion of the solid-state image sensor 112 in accordance with some embodiments of the present disclosure. FIG. 18B is a partial top view illustrating an arrangement of the second shielding segments 32 in accordance with some embodiments of the present disclosure. Similarly, some components of the solid-state image sensor 112 have been omitted in FIG. 18 for the sake of brevity.

Referring to FIG. 18A, the solid-state image sensor 112 may have a similar structure to the solid-state image sensor 100 shown in FIG. 1A. The main difference from the image sensor 100 shown in FIG. 1A is that in the embodiment shown in FIG. 18A, there is no second isolation segments 13S2. In other words, the green color filter segment 20SG and the red color filter segment 20SR (and the blue color filter segment 20SB) are not divided into sub-segments.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A solid-state image sensor, comprising:
photoelectric conversion elements;
a color filter layer disposed above the photoelectric conversion elements and having a first color filter segment and a second color filter segment adjacent to the first color filter segment, wherein the first color filter segment and the second color filter segment correspond to different colors;
a shielding grid structure disposed between the first color filter segment and the second color filter segment, wherein the shielding grid structure is divided into a first shielding segment and a second shielding segment; and
a meta structure disposed above the color filter layer,
wherein in a top view, the second shielding segment is formed as a triangle, a rectangle, or a combination thereof.

2. The solid-state image sensor as claimed in claim 1, wherein in a cross-sectional view, a first width of the first shielding segment is different from a second width of the second shielding segment.

3. The solid-state image sensor as claimed in claim 1, wherein in the top view, the first color filter segment or the second color filter segment is divided into four sub-segments along an X-axis and a Y-axis that is perpendicular to the X-axis.

4. The solid-state image sensor as claimed in claim 3, wherein the second shielding segment is symmetrical with respect to a symmetry axis, and an included angle between the symmetry axis and the X-axis or between the symmetry axis and the Y-axis is 45°.

5. The solid-state image sensor as claimed in claim 3, wherein the second shielding segment is formed as a right triangle, and an included angle between a hypotenuse of the right triangle and the X-axis is between 20° and 80°.

6. The solid-state image sensor as claimed in claim 5, wherein the relationship between the hypotenuse of the right triangle and the X-axis and Y-axis conforms to the following formula:
$$Y = \pm mX + b$$
wherein m=0.36˜5.67, and b=±(0.05˜0.5)×a width of the first color filter segment.

7. The solid-state image sensor as claimed in claim 1, further comprising:
an isolation structure disposed between the photoelectric conversion elements.

8. The solid-state image sensor as claimed in claim 7, wherein the isolation structure has first isolation segments that correspond to the shielding grid structure and second isolation segments that divide the first color filter segment and the second color filter segment into sub-segments.

9. The solid-state image sensor as claimed in claim 8, wherein each of the sub-segments defines a pixel, and a height of the shielding grid structure is in a range from 20 nm to 0.5×a width of the pixel.

10. The solid-state image sensor as claimed in claim 9, wherein from a cross-sectional view, a first width of the first shielding segment is below 0.25×the width of the pixel, and a second width of the second shielding segment is (0.5˜1.5)×the width of the pixel.

11. The solid-state image sensor as claimed in claim 9, wherein in the top view, the second shielding segment has a horizontal width along a first direction and a vertical width along a second direction that is perpendicular to the first direction, and a difference between the horizontal width and the vertical width is (0˜1)×the width of the pixel.

12. The solid-state image sensor as claimed in claim 8, wherein some of the sub-segments partially correspond to the second shielding segment and other of the sub-segments fully correspond to the second shielding segment.

13. The solid-state image sensor as claimed in claim 1, further comprising:
a dielectric grid structure disposed on the shielding grid structure.

14. The solid-state image sensor as claimed in claim 13, wherein the dielectric grid structure fully covers the shielding grid structure.

15. The solid-state image sensor as claimed in claim 13, wherein the dielectric grid structure is divided into a first grid segment that is disposed on the first shielding segment and a second grid segment that is disposed on the second shielding segment.

16. The solid-state image sensor as claimed in claim 15, wherein in a cross-sectional view, the first grid segment and the second grid segment have the same width, and a portion of the second shielding segment extends beyond the second grid segment.

17. The solid-state image sensor as claimed in claim 15, wherein a width of the first grid segment is equal to a first width of the first shielding segment, and a width of the second grid segment is equal to a second width of the second shielding segment.

18. The solid-state image sensor as claimed in claim 1, wherein the first color filter segment is a blue color filter segment or a red color filter segment and the second color filter segment is a green color filter segment.

19. The solid-state image sensor as claimed in claim 18, wherein there are multiple first color filter segments, second color filter segments, first shielding segments, and second shielding segments, and a pair of second shielding segments correspond to the second color filter segments, or a pair of second shielding segments correspond to the first color filter segment.

20. The solid-state image sensor as claimed in claim 19, wherein in a cross-sectional view, widths of the second shielding segments become narrower from a central region of the solid-state image sensor to an edge of the solid-state image sensor.
